(19) United States
(12) Patent Application Publication
(10) Pub. No.: US 2025/0160140 A1
(43) Pub. Date: May 15, 2025

(54) DISPLAY DEVICE AND METHOD OF MANUFACTURING THE SAME

(71) Applicant: Samsung Display Co., LTD., Yongin-si (KR)

(72) Inventors: Hyun Min CHO, Yongin-si (KR); Kyong Chol LEE, Yongin-si (KR); Da Woon JUNG, Yongin-si (KR); Jae Woo JEONG, Yongin-si (KR); Yu Gwang JEONG, Yongin-si (KR)

(21) Appl. No.: 18/933,028

(22) Filed: Oct. 31, 2024

(30) Foreign Application Priority Data
Nov. 14, 2023 (KR) 10-2023-0157610

(51) Int. Cl. H10K 59/126; H10K 59/12; H10K 59/80

(52) U.S. Cl. CPC H10K 59/126; H10K 59/1201; H10K 59/873

(57) ABSTRACT

A display device includes a display panel layer, a light transmission layer disposed on the display panel layer, where a plurality of trenches is defined in the light transmission layer to be recessed in a first direction towards the display panel layer, and a light blocking material filling the plurality of trenches. A profile on a section of each of the plurality of trenches includes a first parallel section, a connection section, and a second parallel section, which are sequentially defined along the first direction. A first width of the profile on the section in a second direction perpendicular to the first direction in the first parallel section is smaller than a second width of the profile on the section in the second direction in the second parallel section.

This application claims priority to Korean patent application No. 10-2023-0157610, filed on Nov. 14, 2023, and all the benefits accruing therefrom under 35 U.S.C. § 119, the content of which in its entirety is herein incorporated by reference.

### BACKGROUND

### 1. Field

Embodiments of the disclosure generally relate to a display device and a method of manufacturing the display device.

### 2. Description of the Related Art

A display device typically includes a display panel layer. The display panel layer may include at least one light emitting element, and light emitted from the light emitting element may be released toward a front surface of the display device. The display device may display an image by combining lights emitted from the light emitting element.

### SUMMARY

Recently, demands for a vehicle including a display device which provides various images such as real-time traffic information have increased. However, light emitted from a display device included in a vehicle may obstruct a driver's field of vision while being reflected from a windshield of the vehicle.

Embodiments provide a display device and a method of manufacturing the display device, in which the viewing angle of an image displayed in the display device is controlled, so that display quality can be improved while preventing emission of unintended light.

In accordance with an embodiment of the disclosure, a display device includes: a display panel layer; a light transmission layer disposed on the display panel layer, where a plurality of trenches is defined in the light transmission layer to be recessed in a first direction towards the display panel layer; and a light blocking material filling the plurality of trenches, where a profile on a section of each of the plurality of trenches includes a first parallel section, a connection section, and a second parallel section, which are sequentially defined along the first direction, and a first width of the profile on the section in a second direction perpendicular to the first direction in the first parallel section is smaller than a second width of the profile on the section in the second direction in the second parallel section.

In an embodiment, a width of the profile on the section in the second direction in the connection section may gradually increase from the first width to the second width along the first direction.

In an embodiment, the profile on the section may further include an upper section as a section between an upper surface of the light transmission layer and the first parallel section. A width of the profile on the section in the second direction in the upper section may gradually increase and then gradually decrease along the first direction.

In an embodiment, a maximum width of the profile on the section in the second direction in the upper section may be smaller than the second width.

In an embodiment, the profile on the section may further include a lower section as a section between the second parallel section and a lower surface of the light transmission layer. In such an embodiment, a width of the profile on the section in the second direction in the lower section may gradually decrease along the first direction.

In an embodiment, the second width may be equal to or smaller than 1.3 times of the first width.

In an embodiment, a sum of a length of the first parallel section in the first direction and a length of the second parallel section in the first direction may be equal to or greater than 60% of a total length of the profile on the section in the first direction.

In an embodiment, the light transmission layer may be a single layer including an organic insulating material.

In an embodiment, the display panel layer may include an inorganic insulating layer in direct contact with a lower surface of the light transmission layer.

In an embodiment, each of the plurality of trenches may expose at least a portion of an upper surface of the inorganic insulating layer.

In accordance with another embodiment of the disclosure, a method of manufacturing a display device includes: forming a preliminary light transmission layer on a display panel layer; forming, on the preliminary light transmission layer, a mask layer defining an opening exposing a portion of an upper surface of the preliminary light transmission layer; forming a light transmission layer defining a plurality of trenches recessed in a first direction towards the display panel layer by dry-etching the preliminary light transmission layer, using the mask layer; and filling the plurality of trenches with a light blocking material, where the mask layer includes a first layer and a second layer disposed on the first layer, and a side surface of the first layer is recessed further in a second direction perpendicular to the first direction than a side surface of the first layer.

In an embodiment, the second layer may have a forward tapered shape on a section.

In an embodiment, the mask layer may further include a third layer disposed on the second layer. In such an embodiment, the side surface of the second layer may be recessed further in the second direction than a side surface of the third layer, to define a first undercut.

In an embodiment, The mask layer may further include a fourth layer disposed on the third layer and a fifth layer disposed on the fourth layer. In such an embodiment, a side surface of the fourth layer may be recessed further in the second direction than each of the side surface of the third layer and a side surface of the fifth layer, to define a second undercut.

In an embodiment, the forming the mask layer may include sequentially forming the first layer and the second layer on the preliminary light transmission layer, performing a first etching process of forming the opening by removing portions of the first layer and the second layer, and performing a second etching process of selectively etching the second layer.

In an embodiment, the first etching process may be a dry etching process, and the second etching process may be a wet etching process.

In an embodiment, an etch selectivity of the second layer with respect to an etchant used in the second etching process may be higher than an etch selectivity of the first layer with respect to the etchant.

In an embodiment, a thickness of the second layer in the first direction may be greater than a thickness of the first layer in the first direction.

In an embodiment, the method may further include removing the mask layer.

In an embodiment, a profile on a section of each of the plurality of trenches may include a first parallel section, a connection section, and a second parallel section, which are sequentially defined along the first direction. In such an embodiment, a first width of the profile on the section in a second direction perpendicular to the first direction in the first parallel section may be smaller than a second width of the profile on the section in the second direction in the second parallel section.

### BRIEF DESCRIPTION OF THE DRAWINGS

The above and other features of the invention will become more apparent by describing in further detail embodiments thereof with reference to the accompanying drawings, in which:

FIG. 1 is a view illustrating a display device in accordance with an embodiment of the disclosure;

FIG. 2 is a sectional view taken along line I-I′ shown in FIG. 1;

FIG. 3 is an enlarged view illustrating area A shown in FIG. 2;

FIG. 4 is an image of the area A shown in FIG. 2;

FIG. 5 is a flowchart illustrating an embodiment of a method of manufacturing the display device shown in FIGS. 1 to 4;

FIGS. 6 to 9 are sectional views illustrating the method of manufacturing the display device, which is shown in FIG. 5;

FIGS. 10 and 11 are sectional views illustrating a method of manufacturing a display device in accordance with another embodiment of the disclosure; and

FIGS. 12 and 13 are sectional views illustrating a method of manufacturing a display device in accordance with still another embodiment of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In the entire specification, when an element is referred to as being “connected” or “coupled” to another element, it can be directly connected or coupled to the another element or be indirectly connected or coupled to the another element with one or more intervening elements interposed therebetween.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

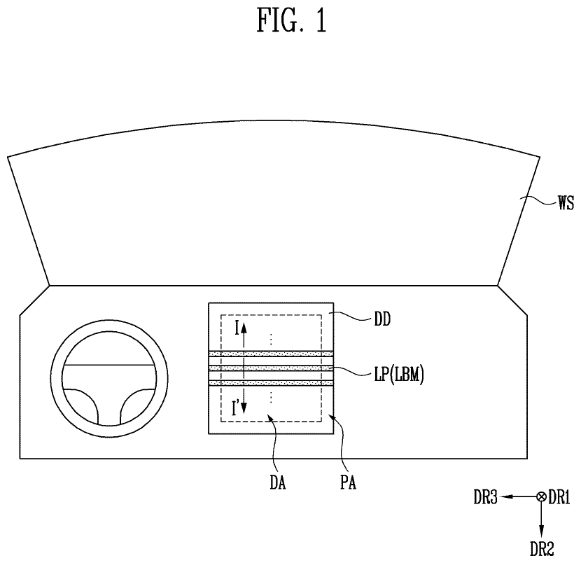

FIG. 1 is a view illustrating a display device in accordance with an embodiment of the disclosure.

Referring to FIG. 1, the display device DD in accordance with an embodiment of the disclosure may include a display area DA for displaying an image and a peripheral area PA adjacent to at least one side of the display area DA. The display area AD may be an area in which an image is displayed by combining lights emitted from the display device DD, and the peripheral area PA may be an area in which a driving circuit for driving the display device DD, or the like are disposed. Hereinafter, for convenience of description, it is considered that the display area DA is on a plane defined by a second direction DR2 and a third direction DR3, which intersect each other, and is substantially parallel to a plane perpendicular to a first direction DR1.

In an embodiment, the display device DD may be a display device for vehicles. In such an embodiment, for example, an image representing real-time traffic information may be displayed in the display area DA of the display device DD.

The display device DD may include a light blocking pattern to prevent the image displayed in the display area DA from being reflected from a windshield WS of a vehicle to obstruct a driver's field of vision. The light blocking pattern may include extension patterns LP which are arranged along the second direction DR2 and include a light blocking material LBM. Each of the extension patterns LP may extend along the third direction DR3, and have a predetermined thickness in the first direction DR1. Accordingly, light emitted in a direction facing (or towards) the windshield WS from the display device DD may be blocked by the extension patterns LP.

Alternatively, light emitted in a direction facing the driver and a fellow passenger from the display device DD may not be blocked by the extension patterns LP. That is, the driver and the fellow passenger may normally view an image displayed based on a combination of lights emitted from the display device DD.

It is desired that a width of each of the extension patterns LP in the second direction DR2 be small enough not to be viewed by the driver and the fellow passenger. When the width of each of the extension patterns LP in the second direction DR2 is relatively large, the extension patterns LP may be viewed by the driver and the fellow passenger, or light emitted from the display device DD may be excessively blocked. Accordingly, the display quality of an image displayed in the display area DA of the display device DD may be deteriorated.

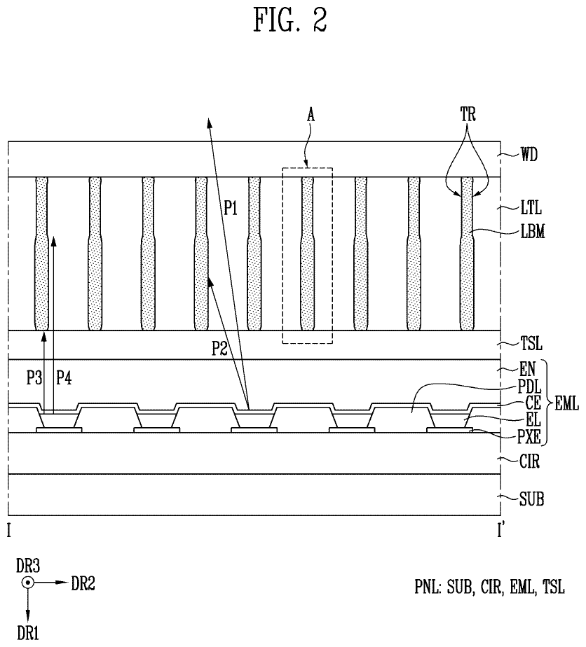

FIG. 2 is a sectional view taken along line I-I′ shown in FIG. 1.

Referring to FIG. 2, an embodiment of the display device DD may include a display panel layer PNL, a light transmission layer LTL, a light blocking material LBM, and a window WD.

The display panel layer PNL may emit light, and an image may be displayed in the display area (DA shown in FIG. 1) by a combination of lights emitted from the display panel layer PNL.

In an embodiment, the display panel layer PNL may include a substrate SUB, a pixel circuit layer CIR, a light emitting element layer EML, and a functional layer TSL.

The substrate SUB may be glass or plastic, and be flexible or rigid.

The pixel circuit layer CIR may be disposed on the substrate SUB. The pixel circuit layer CIR may include at least one transistor constituting a pixel circuit.

The light emitting element layer EML may be disposed on the pixel circuit layer CIR. The light emitting element layer EML may have various structures capable of emitting light, based on an electrical signal received from the pixel circuit layer CIR. In an embodiment, for example, layers included in various types of display devices known in the art, such as an organic light emitting display device, a micro light-emitting diode (LED) display device, an inorganic light emitting display device, and a liquid crystal display, may be used as the light emitting element layer EML without limitation.

Hereinafter, the light emitting element layer EML according to an embodiment where the display device DD is the organic light emitting display device will be described. However, the light emitting element layer EML of an embodiment of the disclosure is not limited to those described herein.

In an embodiment, the light emitting element layer EML may include a pixel electrode PXE, a pixel defining layer PDL, a light emitting layer EL, a common electrode layer CE, and an encapsulation layer EN.

The pixel electrode PXE may be electrically connected to the at least one transistor included in the pixel circuit layer CIR. Accordingly, the pixel electrode PXE may receive an electrical signal from the pixel circuit. In an embodiment, the pixel electrode PXE may be designated as an anode electrode.

The pixel defining layer PDL may be disposed on the pixel circuit layer CIR and the pixel electrode PXE, and define a pixel opening exposing at least a portion of the pixel electrode PXE. In an embodiment, the pixel defining layer PDL may include an organic insulating material and/or an inorganic insulating material.

The light emitting layer EL may be disposed on the pixel electrode PXE in the pixel opening. The light emitting layer EL may emit light, based on an electrical signal provided from the pixel electrode PXE and the common electrode layer CE. In an embodiment, the light emitting layer EL may at least include an organic light emitting material.

The common electrode layer CE may cover the pixel defining layer PDL and the light emitting layer EL. In an embodiment, the common electrode layer CE may be designated as a cathode electrode.

The encapsulation layer EN may cover the common electrode layer CE. The encapsulation layer EN may function to protect the common electrode layer CE or the like from infiltration of moisture and gas. In an embodiment, the encapsulation layer EN may have a triple-layer structure including a first inorganic encapsulation layer, an organic encapsulation layer disposed on the first inorganic encapsulation layer, and a second inorganic encapsulation layer disposed on the organic encapsulation layer.

The functional layer TSL may be disposed on the light emitting element layer. The functional layer TSL may include various types of layers which perform various functions in addition to image display. In an embodiment, for example, the functional layer TSL may include an input sensing layer which senses a touch input of a user. In an embodiment, the functional layer TSL may be omitted.

The light transmission layer LTL disposed on the display panel layer PNL may be provided with a plurality of trenches (or trench holes) TR, which is recessed in the first direction DR1. In an embodiment, as shown in FIG. 2, each of the plurality of trenches TR may be defined through the light transmission layer LTL along the first direction DR1.

In an embodiment, the light transmission layer LTL may include an organic insulating material having a relatively high light transmittance. The light transmission layer LTL may be a single layer including the organic insulating material.

In an embodiment, a bottom surface of the light transmission layer LTL may be in direct contact with the display panel layer PNL. In an embodiment, for example, as shown in FIG. 2, the bottom surface of the light transmission layer LTL may be in direct contact with the functional layer TSL. An uppermost layer in direct contact with the bottom surface of the light transmission layer LTL among various layers constituting the functional layer TSL may be an inorganic insulating layer including an inorganic insulating material.

In another embodiment, where the functional layer TSL is omitted, the bottom surface of the light transmittance layer LTL may be in direct contact with the encapsulation layer EN. An uppermost layer in direct contact with the bottom surface of the light transmission layer LTL among various layers constituting the encapsulation layer EN may be an inorganic insulating layer including an inorganic insulating material.

In an embodiment, each of the plurality of trenches TR may expose at least a portion of an upper surface of the inorganic insulating layer in direct contact with the bottom surface of the light transmission layer LTL.

The light blocking material LBM may be disposed to fill the plurality of trenches TR. The light blocking material LBM may include a material having a relatively high light absorption rate. Accordingly, the light blocking material LBM may block a portion of light emitted from the display panel layer PNL.

The window WD may be disposed on the light transmission layer LTL and the light blocking material LBM. The window WD may include a material having a relatively high hardness while having a relative high light transmittance. In an embodiment, for example, the window WD may include glass, plastic, or the like.

Referring back to FIGS. 1 and 2, the extension patterns LP may be defined by the light blocking material LBM filling the plurality of trenches TR defined in the light transmission layer LTL.

In an embodiment, it is desired to sufficiently secure the thickness of each of the extension patterns LP in the first direction DR1 to effectively block light emitted in a direction facing the windshield WS from the display device DD.

In an embodiment of the disclosure, each of the plurality of trenches TR may have the above-described sufficient length in the first direction DR1 to prevent emission of undesired light. Accordingly, light emitted through a second path P2 facing the windshield WS among lights emitted from the light emitting element layer EML may be blocked by the light blocking material LBM filling the plurality of trenches TR. In such an embodiment, light emitted through a first path P1 not facing the windshield WS may not be blocked by the light blocking material LBM, and may be viewed by a user of the display device DD.

In an embodiment, some of lights emitted in a direction not facing the windshield WS from the display device DD may be blocked by the light blocking material LBM filled in the plurality of trenches TR. In an embodiment, for example, light advancing through a third path P3 parallel to the first direction DR1 may be absorbed into a bottom surface of the light blocking material LBM. When light which does not cause obstruction of a user's field of vision (e.g., reflection from the windshield WS) is absorbed into the light blocking material LBM, the display quality of an image displayed in the display device DD may be deteriorated.

In an embodiment, a width of each of the plurality of trenches TR in the second direction DR2 may be desired to be sufficiently small to prevent the deterioration of the display quality of the display device DD.

In such an embodiment, the width of each of the plurality of trenches TR in the second direction DR2 may be relatively small. in such an embodiment, the width of each of the plurality of trenches TR of the disclosure in the second direction DR2 may be roughly constant. That is, each of the plurality of trenches TR may not substantially include any recessed portion recessed in the second direction DR2 or a direction opposite to the second direction DR2.

Accordingly, light advancing through a fourth path P4 adjacent to the plurality of trenches TR while being parallel to the third path P3 may not be blocked by the light blocking material LBM filled in the plurality of trenches TR. Thus, since the light advancing through the fourth path P4 can normally contribute to image display in the display area DA, the display quality of the display device DD can be further improved.

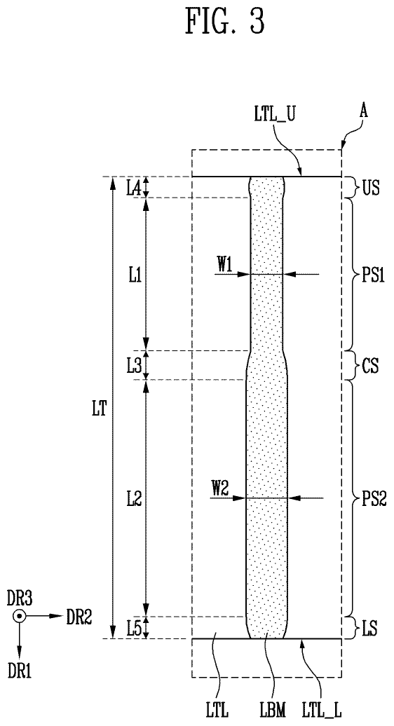

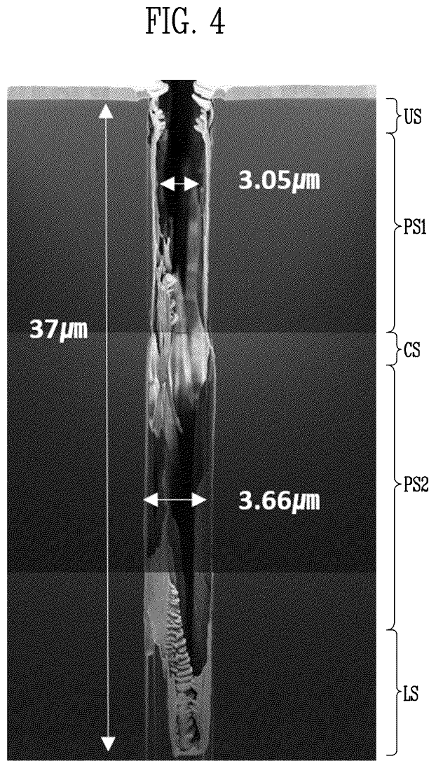

Hereinafter, the plurality of trenches TR in an embodiment of the disclosure will be described in greater detail with reference to FIGS. 3 and 4.

FIG. 3 is an enlarged view illustrating area A shown in FIG. 2. FIG. 4 is an image of the area A shown in FIG. 2.

Referring to FIG. 3, a profile on a section of each of the plurality of trenches TR may include a first parallel section PS1, a connection section CS, and a second parallel section PS2, which are sequentially defined along the first direction DR1.

A width of the profile on the section in the second direction DR2 in the first parallel section PS1 may be substantially constant. That ‘the width is substantially constant’ may mean that a difference between a maximum value and a minimum value of the width of the profile on the section in the second direction DR2 in the first parallel section PS1 is about 5% or less of the maximum value, e.g., about 3% or less.

Similarly, a width of the profile on the section in the second direction DR2 in the second parallel section PS2 may be substantially constant. That is, a difference between a maximum value and a minimum value of the width of the profile on the section in the second direction DR2 in the second parallel section PS2 may be about 5% or less of the maximum value, e.g., about 3% or less.

The width of the profile on the section in the second direction DR2 in the first parallel section PS1 may be a first width W1. That is, the width of the profile on the section in the second direction DR2 in the first parallel section PS1 may be the first width W1 on average.

The width of the profile on the section in the second direction DR2 in the second parallel section PS2 may be a second width W2. That is, the width of the profile on the section in the second direction DR2 in the second parallel section PS2 may be the second width W2 on average. The second width W2 may be greater than the first width W1. In an embodiment, for example, the second width W2 may be greater than the first width W1, and be equal to or smaller than about 1.3 times of the first width W1.

In an embodiment, a width of the profile on the section in the second direction DR2 in the connection section CS may gradually increase from the first width W1 to the second width W2 along (as being towards in) the first direction DR1. That is, in the first parallel section PS1, the connection section CS, and the second parallel section PS2, the width of the profile on the section in the second direction DR2 may be roughly equal to or smaller than the second width W2.

In an embodiment, the profile on the section may further include an upper section US as a section between an upper surface LTL_U of the light transmission layer LTL and the first parallel section PS1, and a width of the profile on the section in the second direction DR2 in the upper section US may gradually increase and then gradually decrease along the first direction DR1. In an embodiment, for example, the width of the profile on the section in the second direction DR2 in the upper section US may gradually increase from the first width W1 and then gradually decrease, thereby again becoming the first width W1.

The profile appearing in the above-described upper section US may be designated as a bowing profile, and the upper section US may be designated as a bowing section. A maximum width of the profile on the section in the second direction DR2 in the upper section US may be smaller than the second width W2. That is, in the upper section US, the first parallel section PS1, the connection section CS, and the second parallel section PS2, the width of the profile on the section may be roughly equal to or smaller than the second width W2. Accordingly, light (e.g., light advancing through the fourth path P4 shown in FIG. 2) which does not cause obstruction of a user's field of vision (e.g., reflection from the windshield WS) may not be substantially blocked by the light blocking material LBM in the upper section US.

In another embodiment, the upper section US may be omitted. That is, the bowing profile may not substantially appear in the profile on the section. The profile on the section may include only the first parallel section PS1 between the upper surface LTL_U of the light transmission layer LTL and the connection section CS.

In an embodiment, the profile on the section may further include a lower section LS between the second parallel section PS and a lower surface LTL_L of the light transmission layer LTL, and a width of the profile on the section in the second direction DR2 in the lower section LS may gradually decrease along the first direction DR1. In an embodiment, for example, the width of the profile on the section in the second direction DR2 in the lower section LS may gradually decrease from the second width W2. That is, in the first parallel section PS1, the connection section CS, the second parallel section PS2, and the lower section LS, the width of the profile on the section in the second direction DR2 may be roughly equal to or smaller than the second width W2.

In an embodiment, a sum of a length L1 of the first parallel section PS1 in the first direction DR1 and a length L2 of the second parallel section PS2 in the first direction DR1 may be equal to or greater than about 60% of a total length LT of the profile on the section in the first direction DR1. That is, each of a length L3 of the connection section CS in the first direction DR1, a length of the upper section US in the first direction DR1, and a length L5 of the lower section LS in the first direction DR1 may be relatively small.

In an embodiment, as described above, the width of the profile on the section of each of the plurality of trenches TR in the second direction DR2 may be equal to or smaller than the second width W2. Accordingly, the width of the light blocking material LBM filling each of the plurality of trenches TR in the second direction DR2 may also be equal to or smaller than the second width W2.

Referring to FIG. 4, in an embodiment, the width of the profile on the section in the second direction DR2 in the first parallel section PS1 may be about 3.05 micrometers (μm), the width of the profile on the section in the second direction DR2 in the second parallel section PS2 may be about 3.66 μm, and the total length of the profile on the section in the first direction DR1 may be about 37 μm.

However, the profile on the section shown in FIG. 4 is merely an example, and the profile on the section of the disclosure may have various profile shapes which are not limited to the image shown in FIG. 4 as long as the profile on the section of the disclosure satisfies the features described above with reference to FIG. 3.

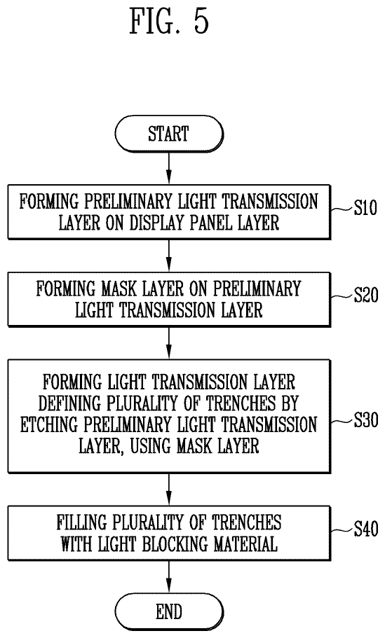

FIG. 5 is a flowchart illustrating an embodiment of a method of manufacturing the display device shown in FIGS. 1 to 4.

Referring to FIG. 5, according to an embodiment of the method of manufacturing the display device, a preliminary light transmission layer may be formed on a display panel layer (S10), a mask layer defining (or provided with) an opening for exposing a portion of an upper surface of the preliminary light transmission layer may be formed on the preliminary light transmission layer (S20), a light transmission layer defining (or provided with) a plurality of trenches recessed in the first direction facing the display panel layer may be formed by dry-etching the preliminary light transmission layer, using the mask layer (S30), and the plurality of trenches may be filled with a light blocking material (S40).

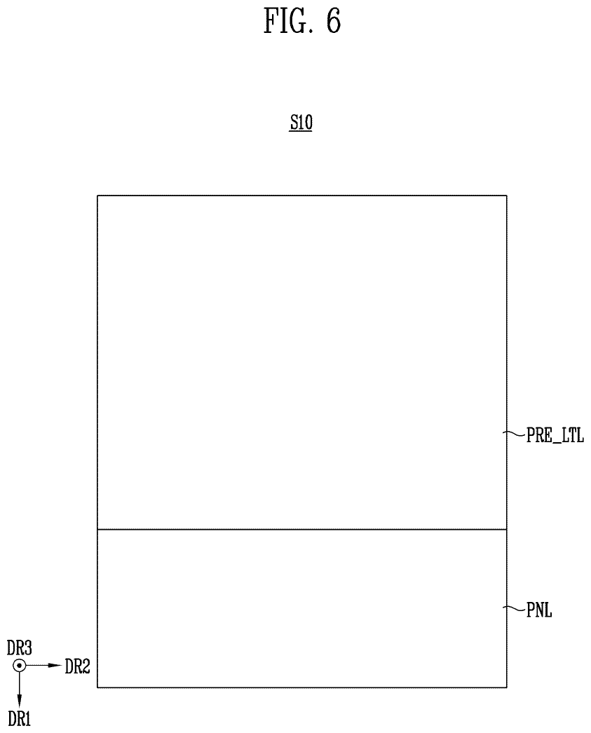

FIGS. 6 to 9 are sectional views illustrating the method of manufacturing the display device, which is shown in FIG. 5. Hereinafter, descriptions of components substantially identical or similar to the components described above with reference to FIGS. 1 to 4 will be omitted.

Referring to FIG. 6, in an embodiment of the method of manufacturing the display device, a preliminary light transmission layer PRE_LTL may be formed on a display panel layer PNL (S10). In an embodiment, the preliminary light transmission layer PRE_LTL may be a single layer including an organic insulating material.

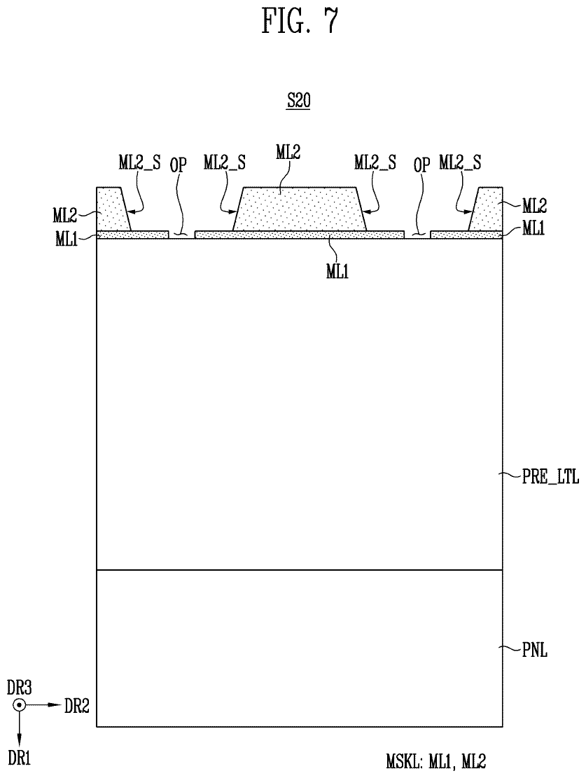

Referring to FIG. 7, a mask layer MSKL defining (or provided with) an opening a portion of an upper surface of the preliminary light transmission layer PRE_LTL may be formed on the preliminary light transmission layer PRE_LTL (S20).

The mask layer MSKL may include a first layer ML1 and a second layer ML2 disposed on the first layer ML1. The second layer ML2 may have a side surface ML2_S recessed as compared with a side surface of the first layer ML1, i.e., the side surface ML2_S recessed further in the second direction DR2 than the side surface of the first layer ML1 defining the opening. That is, the side surface ML2_S of the second layer ML2 adjacent to an opening may be further away from a center of the opening than the side surface of the first layer ML1 defining the opening. In other words, the second layer ML2 may completely overlap the first layer ML1, and have a width narrower than a width of the first layer ML1. Accordingly, an upper surface of the first layer ML1, which does not overlap the second layer ML2, may be exposed in an area adjacent to the opening OP.

In an embodiment, the second layer ML2 may have a forward tapered shape on a section. That is, as shown in FIG. 7, the second layer ML2 may have a trapezoidal shape in which a length of a lower side is longer than a length of an upper side.

In an embodiment, a thickness of the second layer ML2 in the first direction DR1 may be greater than a thickness of the first layer ML1 in the first direction DR1 such that a process margin of the second layer ML2 may be secured in the dry-etching step S30 which will be described later.

In an embodiment, the mask layer MSKL may be formed by sequentially forming the first layer ML1 and the second layer ML2 on the preliminary light transmission layer PRE_LTL and sequentially performing a first etching process of forming the opening OB by removing portions of the first layer ML1 and the second layer ML2 and a second etching process of selectively etching the second layer ML2. The first etching process may be a dry etching process, and the second etching step may be a wet etching process.

In an embodiment, an etch selectivity of the second layer ML2 with respect to an etchant used in the second etching process may be higher than an etch selectivity of the first layer ML1 with respect to the etchant. In an embodiment, for example, the second layer ML2 may include copper or aluminum, which has a relatively high etch selectivity, and the first layer ML1 may include titanium having a relatively low etch selectivity. Accordingly, when the second etching process is performed, the second layer ML2 may be selectively further etched, and the first layer ML1 may not be substantially etched.

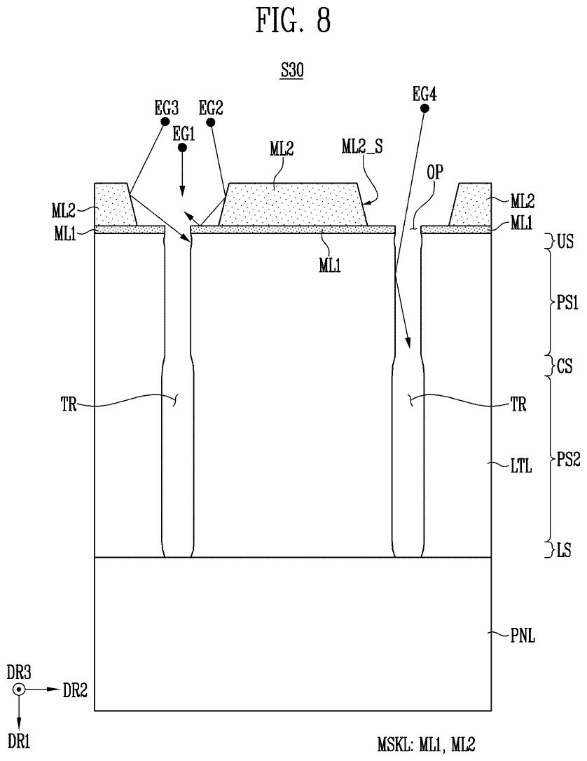

Referring to FIG. 8, a light transmission layer LTL defining a plurality of trenches recessed in the first direction DR1 facing the display panel layer PNL may be formed by dry-etching the preliminary light transmission layer PRE_LTL, using the mask layer MSKL (S30).

In the dry etching, a portion of the preliminary light transmission layer PRE_LTL may be removed by spraying etching particles (e.g., plasma, ions, an etching gas, or the like) in the first direction DR1 and a direction intersecting the first direction DR1. In an embodiment, for example, a first etching particle EG1 advancing in the first direction DR1 may etch the preliminary light transmission layer PRE_LTL while advancing into the opening OP, and accordingly, a profile on a section of the trench TR, including a first parallel section PS1 or the like, may be formed.

In an embodiment, as for second and third etching particles EG2 and EG3 advancing toward the side surface ML2_S of the second layer ML2, the second etching particle EG2 may be scattered from the side surface ML2_S of the second layer ML2 to advance in a direction facing an upper surface of the first layer ML1. After that, the second etching particle EG2 may be scattered from the upper surface of the first layer ML1 once more. Accordingly, the second etching particle EG2 may not advance into the opening OP. That is, the second etching particle EG2 may be blocked by the first layer ML1 of the mask layer MSKL, not to substantially contribute to the etching of the preliminary light transmission layer PRE_LTL.

In such an embodiment, the third etching particle EG3 may be scattered from the side surface ML2_S of the second layer ML2 to advance into the opening OP. The third etching particle EG3 may particularly contribute to etching in an area adjacent to the opening OP. Accordingly, the bowing profile in the upper section US, which has been described with reference to FIG. 3, may be formed by the third etching particle EG3.

In an embodiment of the disclosure, as the side surface ML2_S of the second layer ML2 is recessed as compared with the side surface of the first layer ML1 in the mask layer MSKL, the mask layer MSKL may perform a function of blocking some etching particles EG2 among etching particles EG2 and EG3 having a high possibility to contribute to formation of the above-described bowing profile. Accordingly, the bowing profile can be effectively prevented from being excessively formed.

In an embodiment, some etching particles such as a fourth etching particle EG4 advancing into the opening OP along a direction intersecting the first direction DR1 may be scattered in the first parallel section PS1 of the trench TR. The preliminary light transmission layer PRE_LTL may be etched relatively more in a second parallel section PS2 than in the first parallel section PS1 by the scattered etching particles and other various factors caused by the shape of the above-described mask layer MSKL. Accordingly, a width of the trench TR in the second direction DR2 in the second parallel section PS2 may be greater than a width of the trench TR in the second direction in the first parallel section PS1. In addition, a connection section CS in which the width of the trench TR in the second direction DR2 gradually increases may be formed between the first parallel section PS1 and the second parallel section PS2.

In an embodiment, as various etching conditions including an etching time, a kind of etching particle, or the like are appropriately adjusted, a profile in a lower section LS in which the width of the trench TR in the second direction DR2 gradually decreases may be formed.

In an embodiment, for example, the profile in the lower section LS may be formed as the etching time is set relatively short. If the etching time is set relatively long, as the etching particles are accumulated in an area adjacent to an uppermost layer of the display panel layer PNL, etching may be excessively performed in the area, such that the width of the trench TR in the second direction DR2 may excessively or undesirably increase.

That is, as the etching conditions are appropriately adjusted such that the profile in the lower section LS is formed, the width of the trench TR in the second direction DR2 in the area adjacent to the uppermost layer of the display panel layer PNL may not excessively increase.

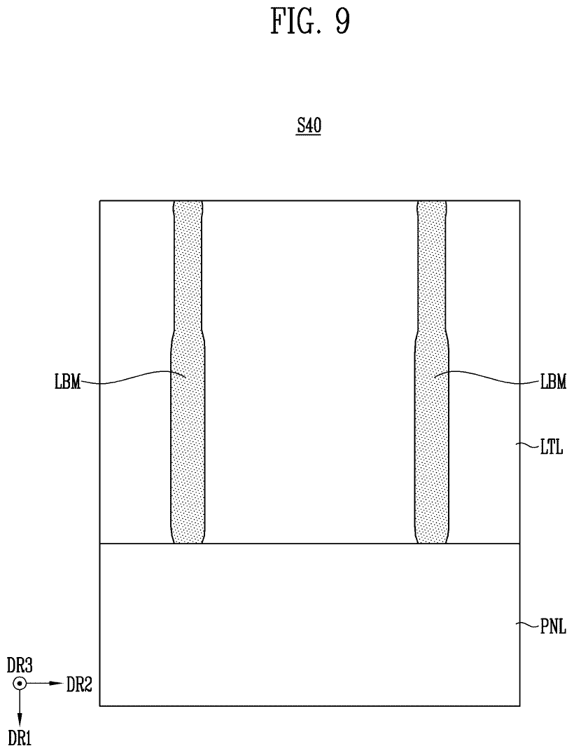

Referring to FIG. 9, the plurality of trenches TR may be filled with a light blocking material LBM (S40). Accordingly, the light blocking material LBM may have a shape on a section, which corresponds to the profile on the section of each of the plurality of trenches TR. The method of filling the plurality of trenches TR with the light blocking material LBM is not limited, and various methods known in the art may be used.

In an embodiment, a process of removing the mask layer MSKL may be further performed. In an embodiment, for example, after the plurality of trenches TR are filled with the light blocking material LBM, components disposed on the upper surface of the light transmission layer LTL may be removed using chemical mechanical polishing (CMP). In another embodiment, for example, the mask layer MSKL may be removed before the process S40 is performed after the process S30 is performed.

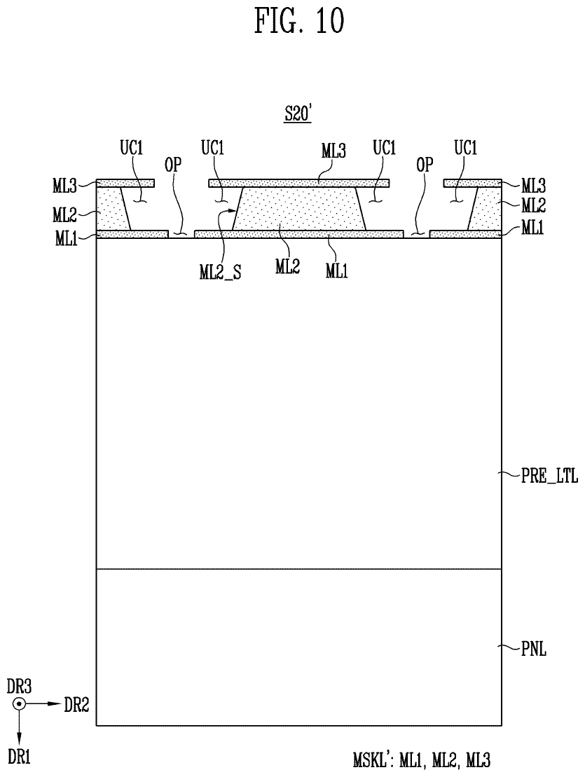

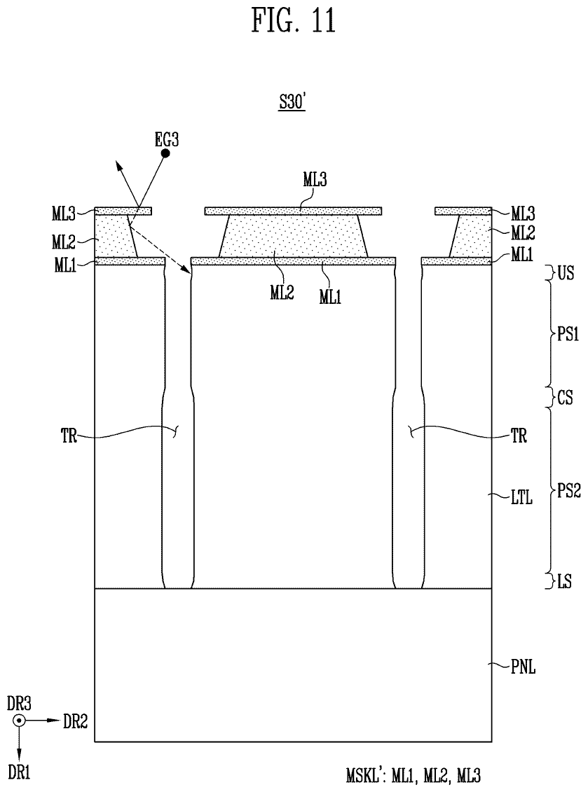

FIGS. 10 and 11 are sectional views illustrating a method of manufacturing a display device in accordance with another embodiment of the disclosure.

Referring to FIGS. 10 and 11, the method of manufacturing the display device in accordance with another embodiment of the disclosure may be substantially identical or similar to the method of manufacturing the display device in accordance with the embodiment of the disclosure described above, except that processes S20′ and S30′ are performed instead of the processes S20 and S230 described with reference to FIG. 5. Therefore, any repetitive detailed descriptions of the same or like processes as those described above may be omitted or simplified.

Referring to FIG. 10, in an embodiment of the method of manufacturing the display device, a mask layer MSKL′ defining (or provided with) an opening OP exposing a portion of an upper surface of a preliminary light transmission layer PRE_LTL may be formed on the preliminary light transmission layer PRE_LTL (S20′).

The mask layer MSKL′ may include a first layer ML1, a second layer ML2 disposed on the first layer ML1, and a third layer ML3 disposed on the second layer ML2. The second layer ML2 may have a side surface ML2_S recessed as compared with a side surface of the first layer ML1, and accordingly, an upper surface of the first layer ML1, which does not overlap the second layer ML2, may be exposed in an area adjacent to the opening OP. Also, the second layer ML2 may have the side surface ML2_S recessed as compared with a side surface of the third layer ML3, and accordingly, a first undercut UC1 may be defined.

In an embodiment, the mask layer MSKL′ may be formed by sequentially forming the first layer ML1, the second layer ML2, and the third layer ML3 on the preliminary light transmission layer PRE_LTL and sequentially performing a first etching process of forming the opening by removing portions of the first layer ML1, the second layer ML2, and the third layer ML3 and a second etching process of selectively etching the second layer ML2. The first etching process may be a dry etching process, and the second etching process may be a wet etching process.

In an embodiment, an etch selectivity of the second layer ML2 with respect to an etchant used in the second etching step may be higher than an etch selectivity of each of the first and third layers ML1 and ML3 with respect to the etchant. In an embodiment, for example, the second layer ML2 may include copper or aluminum, which has a relatively high etch selectivity, and each of the first layer ML1 and the third layer ML3 may include titanium having a relatively low etch selectivity. Accordingly, when the second etching process is performed, the second layer ML2 may be selectively further etched, and the first layer ML1 and the third layer ML3 may not be substantially etched.

Referring to FIG. 11, a light transmission layer LTL defining a plurality of trenches TR recessed in the first direction DR1 facing a display panel layer PNL may be formed by dry-etching the preliminary light transmission layer PRE_LTL, using the mask layer MSKL′ (S30′).

Unlike the process S30 described with reference to FIG. 8, the third layer ML3 may further perform a mask function on etching particles in the process S30′. The third layer ML3 may perform a function of further blocking etching particles such as a third etching particle EG3 advancing toward the side surface ML2_S of the second layer ML2. Accordingly, a change in width of the trench TR in the second direction DR2 in a bowing profile appearing in an upper section US may relatively decrease, or the bowing profile may not substantially appear in the upper section US.

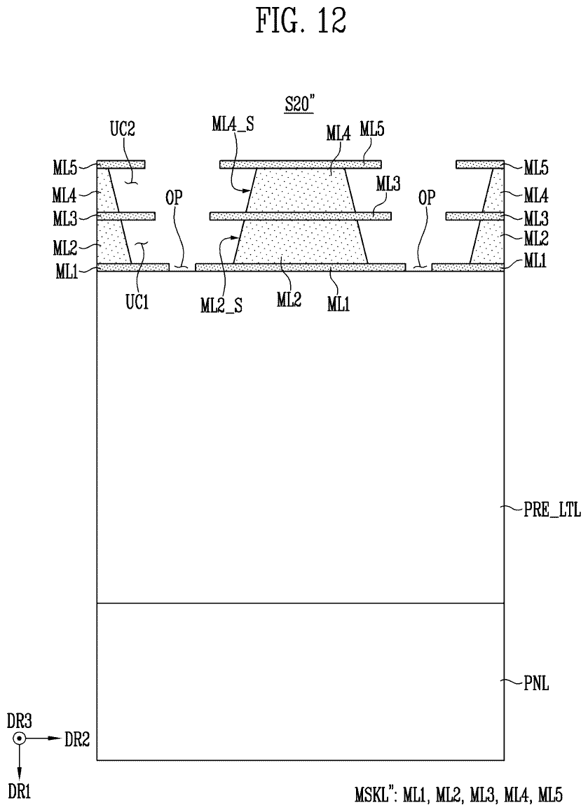

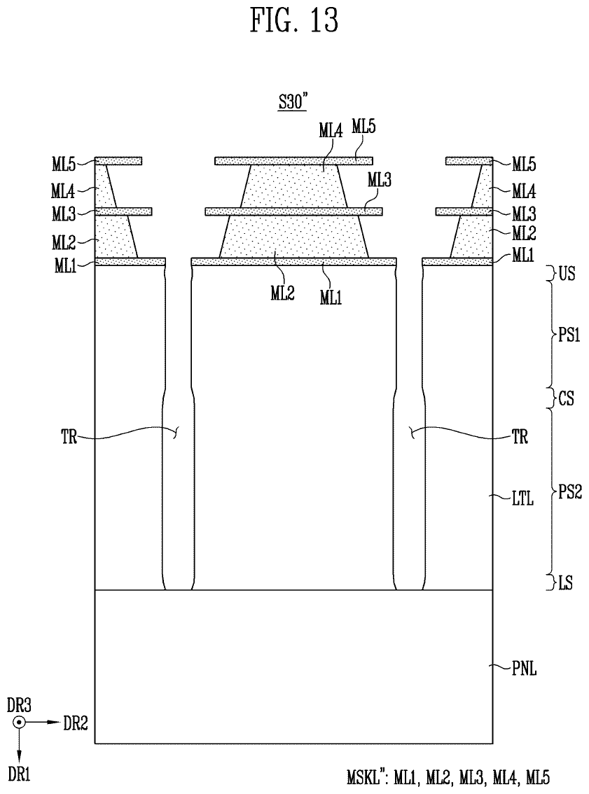

FIGS. 12 and 13 are sectional views illustrating a method of manufacturing a display device in accordance with still another embodiment of the disclosure.

Referring to FIGS. 12 and 13, the method of manufacturing the display device in accordance with another embodiment of the disclosure may be substantially identical or similar to the methods which have been described with reference to FIGS. 5 to 11, except that process S20″ and S30″ are performed instead of the process S20 and S230 described with reference to FIG. 5. Therefore, any repetitive detailed descriptions of the same or like processes as those described above may be partially omitted below.

Referring to FIG. 12, in an embodiment of the method of manufacturing the display device, a mask layer MSKL″ defining (or provided with) an opening OP exposing a portion of an upper surface of a preliminary light transmission layer PRE_LTL may be formed on the preliminary light transmission layer PRE_LTL (S20″).

The mask layer MSKL″ may include a first layer ML1, a second layer ML2 disposed on the first layer ML1, a third layer ML3 disposed on the second layer ML2, a fourth layer ML4 disposed on the third layer ML3, and a fifth layer ML5 disposed on the fourth layer ML4.

The second layer ML2 may have a side surface ML2_S recessed as compared with a side surface of the first layer ML1, and accordingly, an upper surface of the first layer ML1, which does not overlap the second layer ML2, may be exposed in an area adjacent to the opening OP. Also, the second layer ML2 may have the side surface ML2_S recessed as compared with a side surface of the third layer ML3, and accordingly, a first undercut UC1 may be defined.

The fourth layer ML4 may have a side surface ML4_S recessed as compared with the side surface of the third layer ML3, and accordingly, an upper surface of the third layer ML3, which does not overlap the third layer ML3, may be exposed in an area adjacent to the opening OP. Also, the fourth layer ML4 may have the side surface ML4_S recessed as compared with a side surface of the fifth layer ML5, and accordingly, a second undercut UC2 may be defined.

In an embodiment, the mask layer MSKL″ may be formed by sequentially forming the first layer ML1, the second layer ML2, the third layer ML3, the fourth layer ML4, and the fifth layer ML5 on the preliminary light transmission layer PRE_LTL and sequentially performing a first etching process of forming the opening OP by removing portions of the first layer ML1, the second layer ML2, the third layer ML3, the fourth layer ML4, and the fifth layer ML5 and a second etching process of selectively etching the second layer ML2 and the fourth layer ML4. The first etching process may be a dry etching process, and the second etching process may be a wet etching process.

In an embodiment, an etch selectivity of each of the second layer ML2 and the fourth layer ML4 with respect to an etchant used in the second etching process may be higher than an etch selectivity of each of the first layer ML1, the third layer ML3, and the fifth layer ML5 with respect to the etchant. In an embodiment, for example, each of the second layer ML2 and the fourth layer ML4 may include copper or aluminum, which has a relatively high etch selectivity, and each of the first layer ML1, the third layer ML3, and the fifth layer ML5 may include titanium having a relatively low etch selectivity. Accordingly, when the second etching process is performed, the second layer ML2 and the fourth layer ML4 may be selectively further etched, and the first layer ML1, the third layer ML3, and the fifth layer ML5 may not be substantially etched.

Referring to FIG. 13, a light transmission layer LTL defining a plurality of trenches TR recessed in the first direction DR1 facing a display panel layer PNL may be formed by dry-etching the preliminary light transmission layer PRE_LTL, using the mask layer MSKL″ (S30″).

Unlike the processes S30 and S30′ described with reference to FIGS. 8 and 11, the fourth and fifth layers ML4 and ML5 may perform a mask function on etching particles in the process S30″. The fourth layer ML4 may perform a function substantially identical or similar to the function performed by the second layer ML2, which has described with reference to FIG. 8, and the fifth layer ML5 may perform a function substantially identical or similar to the function performed by the third layer ML3, which has described with reference to FIG. 11.

In accordance with embodiments of a display device and a method of manufacturing the display device, the viewing angle of an image displayed in the display device is controlled, such that display quality can be improved while preventing emission of unintended or undesired light.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel layer;
a light transmission layer disposed on the display panel layer, wherein a plurality of trenches is defined in the light transmission layer to be recessed in a first direction towards the display panel layer; and
a light blocking material filling the plurality of trenches,
wherein a profile on a section of each of the plurality of trenches includes a first parallel section, a connection section, and a second parallel section, which are sequentially defined along the first direction, and
wherein a first width of the profile on the section in a second direction perpendicular to the first direction in the first parallel section is smaller than a second width of the profile on the section in the second direction in the second parallel section.

2. The display device of claim 1, wherein a width of the profile on the section in the second direction in the connection section gradually increases from the first width to the second width along the first direction.

3. The display device of claim 1, wherein the profile on the section further includes an upper section as a section between an upper surface of the light transmission layer and the first parallel section, and
wherein a width of the profile on the section in the second direction in the upper section gradually increases and then gradually decreases along the first direction.

4. The display device of claim 3, wherein a maximum width of the profile on the section in the second direction in the upper section is smaller than the second width.

5. The display device of claim 1, wherein the profile on the section further includes a lower section as a section between the second parallel section and a lower surface of the light transmission layer, and
wherein a width of the profile on the section in the second direction in the lower section gradually decreases along the first direction.

6. The display device of claim 1, wherein the second width is equal to or smaller than 1.3 times of the first width.

7. The display device of claim 1, wherein a sum of a length of the first parallel section in the first direction and a length of the second parallel section in the first direction is equal to or greater than 60% of a total length of the profile on the section in the first direction.

8. The display device of claim 1, wherein the light transmission layer is a single layer including an organic insulating material.

9. The display device of claim 8, wherein the display panel layer includes an inorganic insulating layer in direct contact with a lower surface of the light transmission layer.

10. The display device of claim 9, wherein each of the plurality of trenches exposes at least a portion of an upper surface of the inorganic insulating layer.

11. A method of manufacturing a display device, the method comprising:
forming a preliminary light transmission layer on a display panel layer;
forming, on the preliminary light transmission layer, a mask layer defining an opening exposing a portion of an upper surface of the preliminary light transmission layer;
forming a light transmission layer defining a plurality of trenches recessed in a first direction towards the display panel layer by dry-etching the preliminary light transmission layer, using the mask layer; and
filling the plurality of trenches with a light blocking material,
wherein the mask layer includes a first layer and a second layer, which is disposed on the first layer, and
wherein a side surface of the first layer is recessed further in a second direction perpendicular to the first direction than a side surface of the first layer.

12. The method of claim 11, wherein the second layer has a forward tapered shape on a section.

13. The method of claim 11, wherein the mask layer further includes a third layer disposed on the second layer, and
wherein the side surface of the second layer is recessed further in the second direction than a side surface of the third layer, to define a first undercut.

14. The method of claim 13, wherein the mask layer further includes a fourth layer disposed on the third layer and a fifth layer disposed on the fourth layer, and
wherein a side surface of the fourth layer is recessed further in the second direction than a each of the side surface of the third layer and a side surface of the fifth layer, to define a second undercut.

15. The method of claim 11, wherein the forming the mask layer includes:
sequentially forming the first layer and the second layer on the preliminary light transmission layer;
performing a first etching process of forming the opening by removing portions of the first layer and the second layer; and
performing a second etching process of selectively etching the second layer.

16. The method of claim 15, wherein
the first etching process is a dry etching process, and
the second etching process is a wet etching process.

17. The method of claim 16, wherein an etch selectivity of the second layer with respect to an etchant used in the second etching process is higher than an etch selectivity of the first layer with respect to the etchant.

18. The method of claim 15, wherein a thickness of the second layer in the first direction is greater than a thickness of the first layer in the first direction.

19. The method of claim 11, further comprising:
removing the mask layer.

20. The method of claim 11, wherein a profile on a section of each of the plurality of trenches includes a first parallel section, a connection section, and a second parallel section, which are sequentially defined along the first direction, and
wherein a first width of the profile on the section in a second direction perpendicular to the first direction in the first parallel section is smaller than a second width of the profile on the section in the second direction in the second parallel section.
